(19) United States
(12) Patent Application Publication
(10) Pub. No.: US 2013/0140700 A1
(43) Pub. Date: Jun. 6, 2013

(54) METHOD OF MANUFACTURING A SEMICONDUCTOR DEVICE AND SEMICONDUCTOR DEVICE

(71) Applicant: Tadahiro Ohmi, Miyagi (JP)

(72) Inventor: Tadahiro Ohmi, Miyagi (JP)

(73) Assignee: NATIONAL UNIVERSITY CORPORATION TOHOKU UNIVERSITY, Miyagi (JP)

(21) Appl. No.: 13/814,950

(22) PCT Filed: Aug. 4, 2011
(86) PCT No.: PCT/JP2011/067847

§ 371 Date: Feb. 8, 2013

(30) Foreign Application Priority Data
Aug. 10, 2010 (JP) 2010-179468

(51) Int. Cl. H01L 23/48; H01L 21/768

(52) U.S. Cl. CPC H01L 23/481; H01L 21/76843
USPC 257/751; 438/653

(57) ABSTRACT

Provided is a method of manufacturing a TSV structure, which prevents a substrate from warping even if it is made thin. A method of manufacturing a semiconductor device comprises integrating semiconductor elements on a surface of a semiconductor substrate to form at least a part of a circuit, forming holes from the surface of the semiconductor substrate, forming an insulating film and a barrier film on an inner surface of each hole, forming a conductive metal on a surface of the barrier film to fill each hole, processing a back surface of the semiconductor substrate to reduce the thickness thereof to thereby protrude the conductive metal, and providing a SiCN film on the back surface of the semiconductor substrate.

### TECHNICAL FIELD

This invention relates to a method of manufacturing a semiconductor device including a TSV structure and to the semiconductor device.

### BACKGROUND ART

In recent years, with ultra-high densification of semiconductor LSIs, a technique has been employed in which, in order to three-dimensionally form an LSI, a semiconductor device (semiconductor chip or semiconductor wafer) includes a TSV (Through Silicon Via, through-silicon electrode) structure, i.e. is provided with through electrodes passing through the inside of the semiconductor device, and end portions of the through electrodes are connected to electrodes of another semiconductor device, thereby forming a three-dimensional structure.

With the TSV structure, when a plurality of semiconductor devices are stacked together, the semiconductor devices are connected to each other via through electrodes and, therefore, bonding pads, an interposer layer, or the like for the connection is not required so that the semiconductor devices can be made smaller in size.

Herein, in the semiconductor device including the TSV structure, in order to further reduce the thickness of the device, there is a case where a number of required holes are formed in a silicon substrate (wafer) which is formed with a circuit, then an electrode metal post of Cu or W is formed as a TSV in each of the holes, then processing such as etching is carried out from a back surface of the wafer to reduce the thickness of the wafer and to cause the electrode metal posts to protrude from the back surface (Patent Document 1).

### PRIOR ART DOCUMENT

### Patent Document

Patent Document 1: JP-A-2010-114155

### SUMMARY OF THE INVENTION

### Problem to be Solved by the Invention

However, there has been a problem that while the thickness of the substrate can be reduced by the above-mentioned processing, the substrate tends to warp in that event.

This invention has been made in view of the above-mentioned problem and a technical subject of this invention is to provide a method of manufacturing a semiconductor device including a TSV structure, which can prevent a substrate from warping even if it is made thin.

### Means for Solving the Problem

In order to solve the above-mentioned problem, according to a first aspect of this invention, there is provided a method of manufacturing a semiconductor device, characterized by comprising a step (a) of integrating semiconductor elements on a surface of a semiconductor substrate to form at least a part of a circuit, a step (b) of forming a hole from the surface of the semiconductor substrate, a step (c) of forming an insulating film and a barrier film on an inner surface of the hole, a step (d) of forming a conductive metal on an inner surface of the barrier film to fill the hole, a step (e) of then processing a back surface of the semiconductor substrate to reduce a thickness of the semiconductor substrate to thereby protrude the conductive metal, the barrier film, and the insulating film from the back surface, and a step (f) of then providing a SiCN film on the back surface of the semiconductor substrate.

According to a second aspect of this invention, there is provided a semiconductor device characterized by comprising a semiconductor substrate formed with semiconductor elements on a surface thereof, a through electrode which is provided to pass through the semiconductor substrate and to partly protrude from a back surface of the semiconductor substrate, and a SiCN film which is provided to cover the back surface.

### Effect of the Invention

According to this invention, it is possible to provide a method of manufacturing a semiconductor device including a TSV structure, which can prevent a substrate from warping even if it is made thin.

### BRIEF DESCRIPTION OF THE DRAWINGS

FIG. 1 is a cross-sectional view showing a semiconductor device 100.

FIG. 2 is a cross-sectional view showing a manufacturing process of the semiconductor device 100.

FIG. 3 is a cross-sectional view showing a manufacturing process of the semiconductor device 100.

FIG. 4 is a cross-sectional view showing a manufacturing process of the semiconductor device 100.

FIG. 5 is a cross-sectional view showing a manufacturing process of the semiconductor device 100.

FIG. 6 is a cross-sectional view showing a manufacturing process of the semiconductor device 100.

FIG. 7 is a cross-sectional view showing a manufacturing process of the semiconductor device 100.

FIG. 8 is a cross-sectional view showing a manufacturing process of the semiconductor device 100.

FIG. 9 is a cross-sectional view showing a manufacturing process of the semiconductor device 100.

FIG. 10 is a diagram showing the relationship between the composition and the physical property (internal stress) of a SiCN film 20.

### MODE FOR CARRYING OUT THE INVENTION

Hereinbelow, a preferred embodiment of this invention will be described in detail with reference to the drawings.

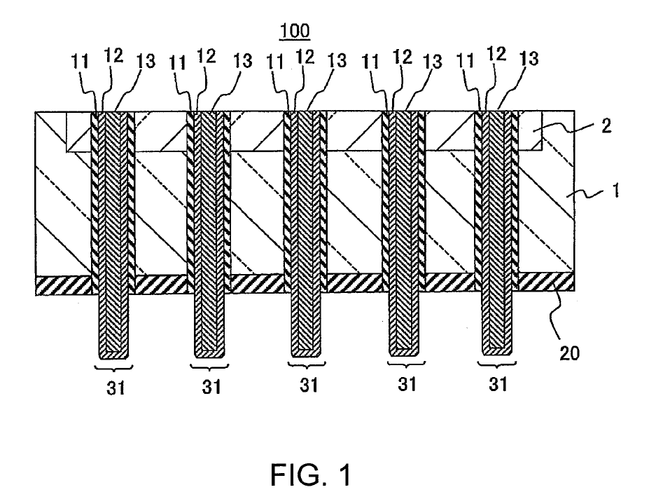

First, referring to FIG. 1, the structure of a semiconductor device 100 according to this embodiment will be described.

As shown in FIG. 1, the semiconductor device 100 comprises a substrate 1 such as a silicon substrate and a circuit 2 configured as an LSI of DRAMs, flash memories, or the like is formed on a surface of the substrate 1 by integrating non-illustrated semiconductor elements.

Further, the semiconductor device 100 is formed with through electrodes 31 (TSVs) which pass through the substrate 1 and partly protrude from a back surface (surface on the opposite side of the surface where the circuit 2 is formed) of the substrate 1.

The through electrode 31 comprises a columnar plug 13 formed of a conductive metal such as Cu and a barrier film 12 of TaN or the like which is formed to cover the plug 13.

Further, an insulating film 11 of Si₃N₄ or the like is provided between the through electrode 31 and the substrate 1 so as to cover the through electrode 31 and to be in contact with the substrate 1.

On the other hand, a SiCN film 20 is formed on the back surface of the substrate 1, thereby covering the back surface.

The SiCN film 20 is a passivation film which is provided on the back surface of the substrate for preventing warping of the substrate 1. In general, a silicon oxide film or a silicon nitride film is used as a passivation film. However, there is a problem that such a film causes warping of a thin substrate. Although details will be described later, since the internal stress of the SiCN film 20 changes depending on the C content in the film, warping of the wafer can be made substantially zero by controlling the C content in the film formation.

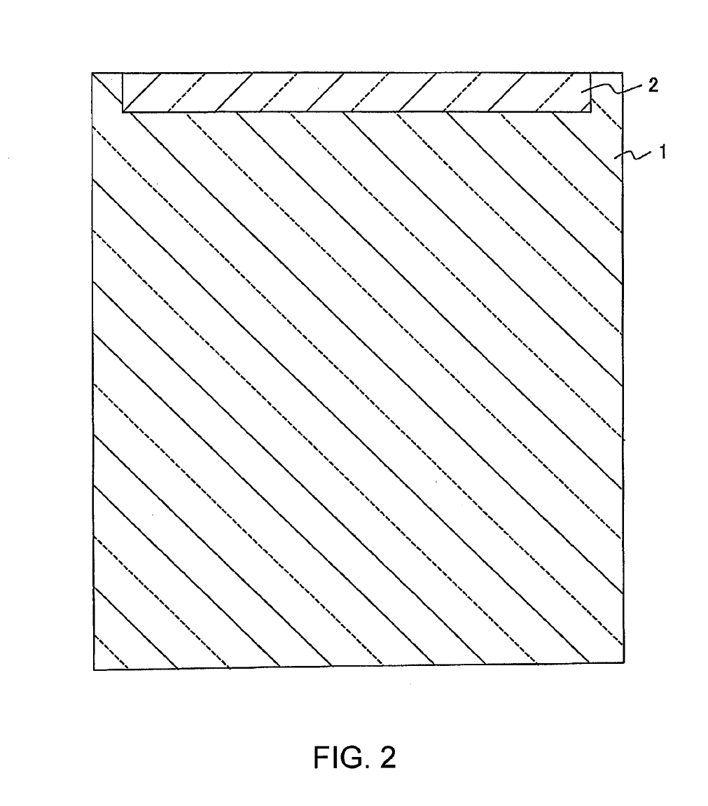

Next, referring to FIGS. 2 to 10, a method of manufacturing the semiconductor device 100 will be described.

First, a substrate 1 as shown in FIG. 2 is prepared.

As described above, a silicon substrate or the like is used as the substrate 1 and a circuit 2 is formed entirely or partly on a surface of the substrate 1 by integrating non-illustrated semiconductor elements.

Herein, the silicon substrate having a thickness of 775 μm is prepared as the substrate 1 and the circuit 2 configured as an LSI of DRAMs, flash memories, or the like is formed on the surface of the substrate 1 by integrating the semiconductor elements.

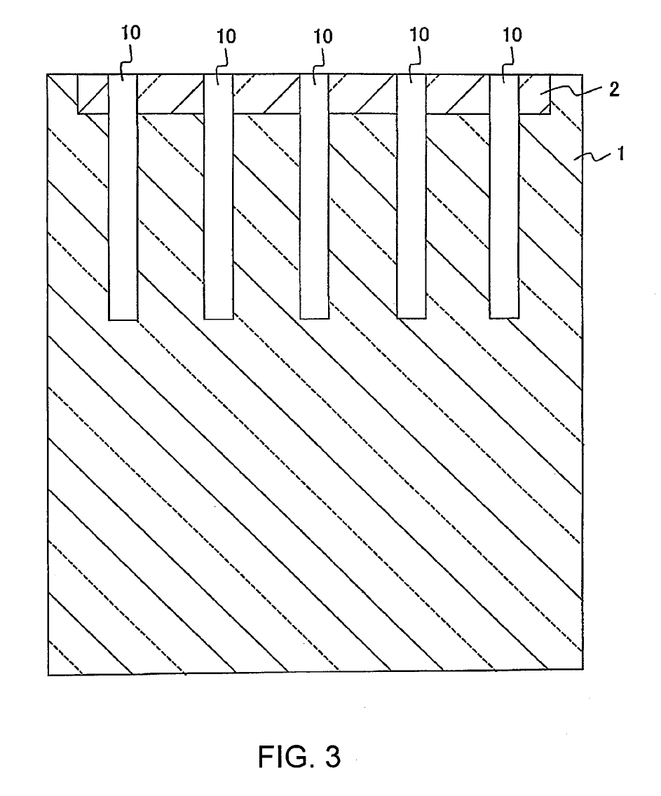

Then, as shown in FIG. 3, a predetermined number of holes 10 are formed from the surface at portions, where a TSV structure (through electrodes 31) is to be formed, of the substrate 1.

Herein, the size of the hole 10 is set to about 10 μm×10 μm and the depth thereof is set to about 40 μm to 50 μm.

The perforation is carried out, for example, by etching. Specifically, the perforation etching is carried out using a 2.45 GHz microwave-excited RLSA plasma etcher or a 915 MHz microwave-excited MSEP (Metal Surfacewave Excitation Plasma) plasma etcher.

In each of these etchers, an inner wall surface of a chamber is covered with an Al₂O₃ film by anodic oxidation of a nonaqueous solution and thus no water is introduced at all. If all organic solvent or water of a resist is removed in advance, the etching selectivity of Si to the resist becomes 50 to 100. As a consequence, the thickness of the resist may be as thin as about 2 μm so that the resolution can be increased correspondingly.

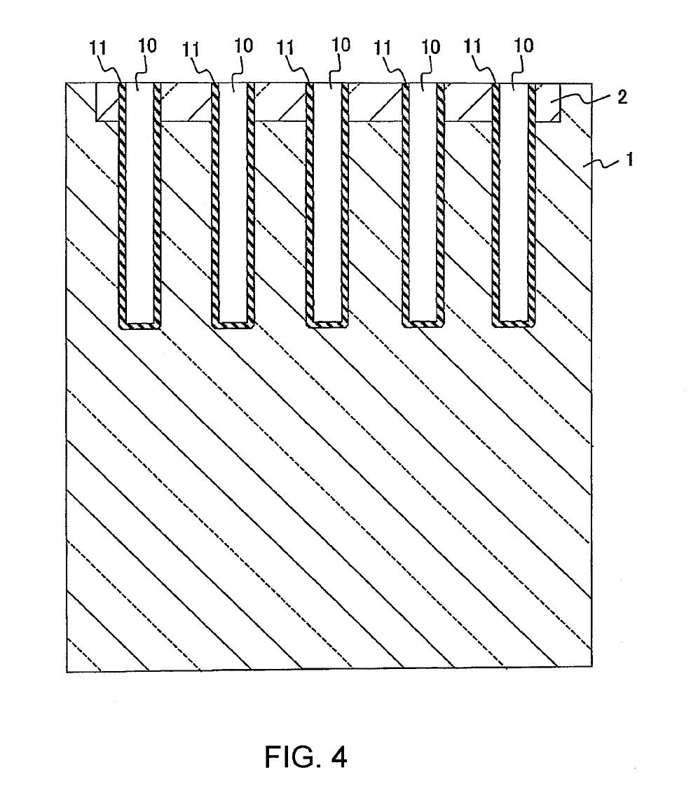

Then, as shown in FIG. 4, an insulating film 11 is formed on an inner surface of each hole 10. As a method of forming the insulating film 11, use may be made of a method of directly nitriding Si and then forming a silicon nitride film thereon by CVD.

In this case, using a 915 MHz microwave-excited single-shower-plate MSEP plasma processing apparatus, the direct nitridation is carried out by supplying a mixed gas of Ar gas and NH₃ gas from a shower plate. Then, a Si₃N₄ film is formed by CVD (Chemical Vapor Deposition) on the silicon nitride.

Using a 915 MHz microwave-excited dual-shower-plate MSEP plasma processing apparatus, the CVD is carried out by supplying a mixed gas of Ar gas and NH₃ gas from an upper shower plate and supplying a mixed gas of Ar gas and SiH₄ gas from a lower shower plate.

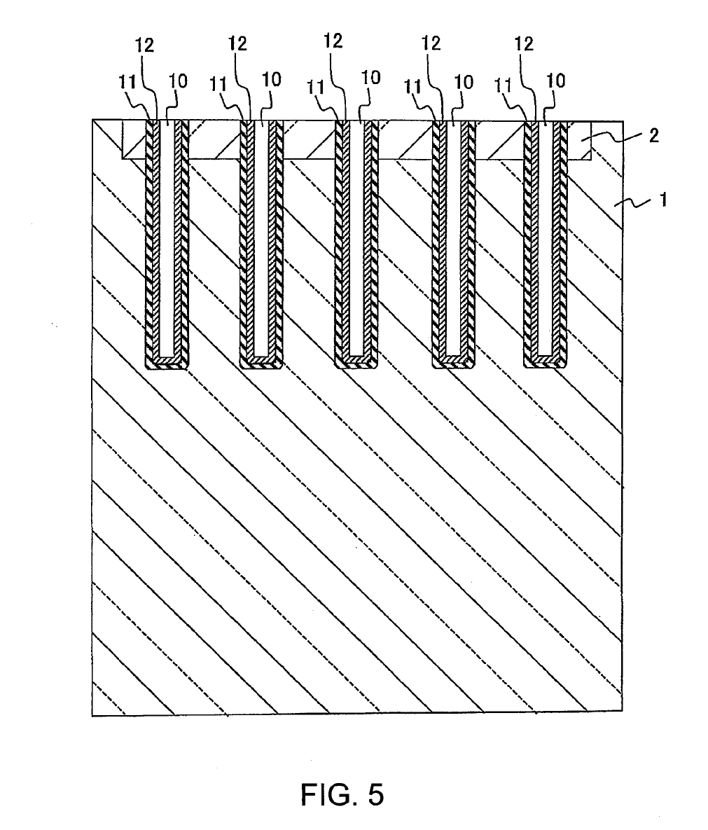

Then, as shown in FIG. 5, a barrier film 12 is formed on an inner surface of the insulating film 11. Herein, using a 915 MHz microwave-excited dual-shower-plate MSEP plasma processing apparatus which is the same as that used in the formation of the insulating film 11, a TaN film is formed by CVD as the barrier film 12 on the Si₃N₄ film by supplying a mixed gas of Ar gas and NH₃ gas from an upper shower plate and supplying a gas such as TaCl₃ from a lower shower plate. This barrier film 12 is a conductive barrier film for preventing Cu, which will be formed into a film subsequently, from diffusing into the semiconductor substrate.

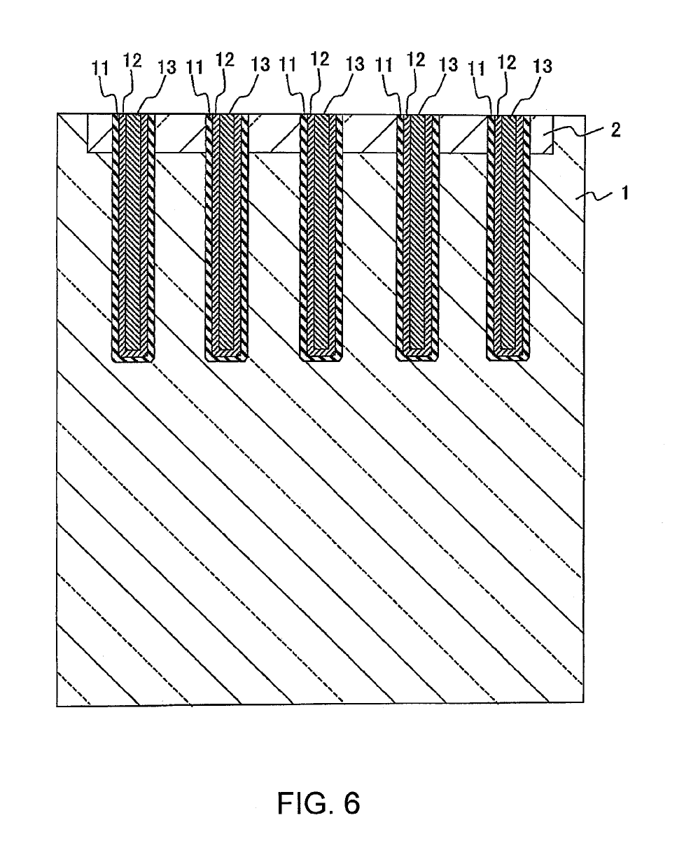

Then, as shown in FIG. 6, a plug 13 is formed in each hole 10 to fill the hole 10. Herein, a current is supplied to the TaN film (barrier film 12) to carry out electroplating of Cu on an inner surface of the TaN film using the TaN film as a seed film, thereby forming a Cu metal post (TSV electrode) as the plug 13.

In this manner, the TSV electrodes (through electrodes 31) are formed in the respective holes 10.

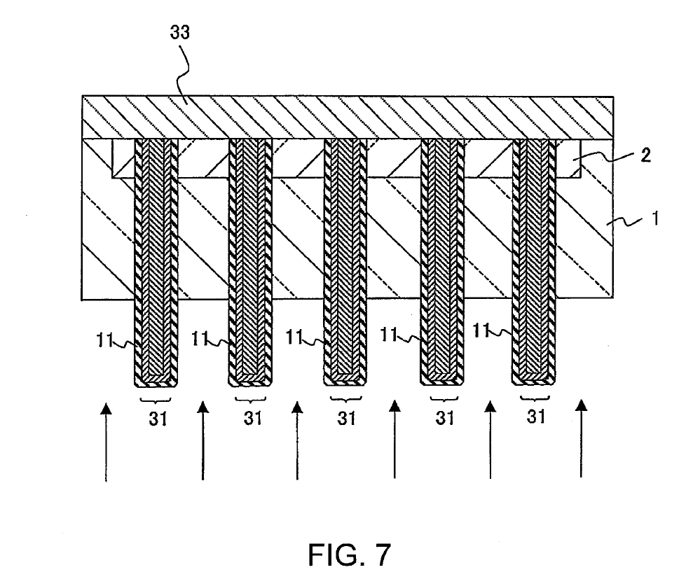

Then, as shown in FIG. 7, etching is carried out from the back surface side of the substrate 1 to reduce the thickness of the substrate 1 to a predetermined thickness and to cause a part, on the bottom side, of each TSV electrode (plug 13) covered with the TaN film 12 and the insulating film 11 to protrude (be exposed) from the back surface of the substrate 1.

While the substrate 1 is bonded on its front surface side to a porous glass substrate 33 (manufactured by Tokyo Ohka), the etching is carried out by ultra-high-rate wet etching at a rate of 750 μm/min for about 1 minute on the back surface side of the silicon substrate 1 of 775 μm, using a HF/HNO₃/CH₃COOH/H₂O solution. As a result, the thickness of the substrate 1 becomes about 20 μm to 30 μm. In this event, since the Si₃N₄ film (insulating film 11) is not etched, the substrate 1 can be reduced in thickness only by the wet etching.

As is clear from FIG. 7, the bottom side of the Cu plugs 13 each covered with the TaN film (barrier film 12) and the Si₃N₄ film (insulating film 11) protrudes on the back surface side of the substrate 1 having the reduced thickness of 20 μm to 30 μm.

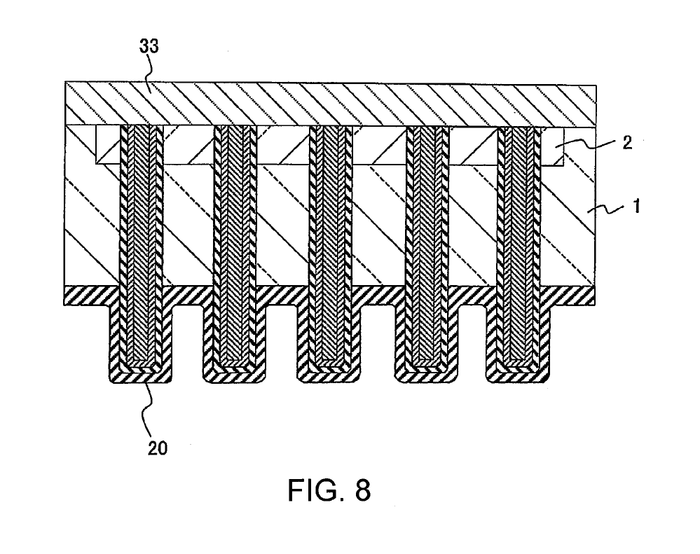

Then, as shown in FIG. 8, a SiCN film 20 is formed by CVD on the back surface of the substrate 1.

Specifically, using a 915 MHz microwave-excited dual-shower-plate MSEP plasma processing apparatus, the SiCN film 20 is formed at a temperature of about 100° C. by supplying a mixed gas of Ar gas and NH₃ gas from an upper shower plate and supplying a mixed gas of Ar gas, SiH₄ gas, and SiH(CH₃)₃ gas from a lower shower plate.

As a result, it is possible to completely control warping of the wafer (substrate 1).

That is, since the internal stress of SiCN changes from positive to negative at a C content of about 10 at %, a condition that makes warping of the wafer zero can be found by controlling the C content.

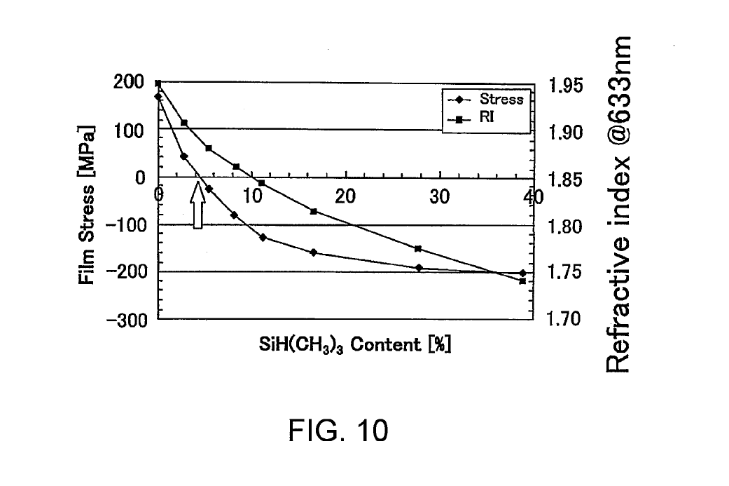

Specifically, as indicated by a white arrow in FIG. 10, the internal stress of the SiCN film 20 can be made substantially zero, for example, by adjusting the concentration of the SiH(CH₃)₃ gas (i.e. by adjusting the C content in the film).

Silicon nitride Si₃N₄ with C contained (added) in an amount slightly less than 10% is the best as a composition of SiCN while a composition added with 2 at % to 40 at % C may also be satisfactory.

Further, SiCN has a feature that it is not only excellent in properties as a passivation film, but also excellent in thermal conductivity. While SiO₂ has a thermal conductivity of 1.4 W/m/Kelvin, SiCN has an overwhelmingly greater thermal conductivity of 70 W/m/Kelvin.

Accordingly, by forming the SiCN film 20 on the back surface of the substrate 1, it is possible to achieve both the complete protective film function and the control of warping of the wafer as described above.

As shown in FIG. 8, when forming SiCN, the SiCN film 20 is formed also on surfaces of the protruding portions of the Cu plugs 13 each covered with the TaN film (barrier film 12) and the Si₃N₄ film (insulating film 11).

Thereafter, the wafer (substrate 1) is stripped from the glass substrate 33. Since the glass substrate 33 is, if it is bare, gradually etched with the wet-etching HF/HNO₃/CH₃COOH/H₂O solution, an exposed surface thereof is covered with a non-illustrated protective film as an etching stopper, which is obtained by coating Y₂O₃ added with CeO₂ and baking it at about 700° C.

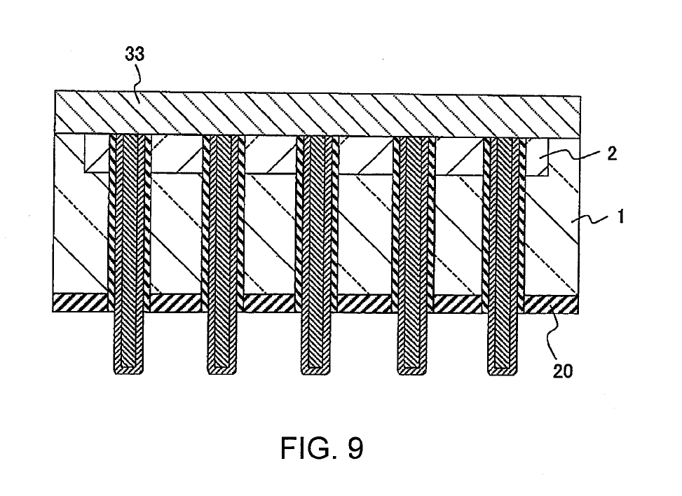

Before stripping off the glass substrate 33, as shown in FIG. 9, on the back surface side of the substrate 1, a resist is coated on a surface of the SiCN film 20 (portion formed on the back surface of the silicon substrate), thereby removing, by etching, the SiCN film 20 and the Si₃N₄ film (insulating film 11) covering a surface of each through electrode 31 (surface of each barrier film 12 protruding from the back surface of the substrate 1).

Through the processes described above, the semiconductor device 100 shown in FIG. 1 is completed.

As described above, according to this embodiment, the semiconductor device 100 is manufactured by forming the holes 10 in the substrate 1, then forming the insulating film 11, the barrier film 12, and the plug 13 in each hole 10, then etching the back surface of the substrate 1 to reduce the thickness of the substrate 1 to thereby protrude the insulating films 11, the barrier films 12, and the plugs 13, and then forming the SiCN film 20 on the back surface of the substrate 1.

Consequently, according to the method of manufacturing the semiconductor device including the TSV structure of this invention, it is possible to prevent warping of the substrate 1 even if the substrate 1 is reduced in thickness by etching.

### INDUSTRIAL APPLICABILITY

In the above-mentioned embodiment, the description has been given of the case where this invention is applied to the semiconductor device 100 using the silicon substrate which is formed on its surface with the DRAMs or the flash memories. However, this invention is by no means limited thereto and can be applied to all TSV structures.

### DESCRIPTION OF SYMBOLS

1 substrate
2 circuit (LSI configuration)
10 hole
11 insulating film
12 barrier film (TaN film)
13 plug (conductive metal)
20 SiCN film
31 through electrode
33 glass substrate
100 semiconductor device

1. A method of manufacturing a semiconductor device, comprising:
(a) integrating semiconductor elements on a surface of a semiconductor substrate to form at least a part of a circuit;
(b) forming a hole from the surface of the semiconductor substrate;
(c) forming an insulating film and a barrier film on an inner surface of the hole;
(d) forming a conductive metal on an inner surface of the barrier film to fill the hole;
(e) processing a back surface of the semiconductor substrate to reduce a thickness of the semiconductor substrate to thereby protrude the conductive metal, the barrier film, and the insulating film from the back surface; and
(f) providing a SiCN film on the back surface of the semiconductor substrate.

2. The method of manufacturing a semiconductor device according to claim 1, wherein the (f) comprises controlling a composition of the SiCN film so that warping of the semiconductor substrate becomes substantially zero.

3. The method of manufacturing a semiconductor device according to claim 1, wherein the (f) comprises forming the SiCN film having a composition in which 2 at % to 40 at % C is added to Si₃N₄.

4. The method of manufacturing a semiconductor device claim 1, wherein the (e) comprises reducing the thickness of the semiconductor substrate by etching the back surface of the semiconductor substrate.

5. The method of manufacturing a semiconductor device according to claim 1, wherein the (e) comprises reducing the thickness of the semiconductor substrate by bonding the semiconductor substrate on its front surface side to a porous glass substrate and wet-etching the back surface of the semiconductor substrate.

6. The method of manufacturing a semiconductor device according to claim 1, wherein the (f) comprises a, after forming the SiCN film by CVD on the back surface of the semiconductor substrate, removing the insulating film and the SiCN film formed on a surface of the barrier film protruding from the back surface.

7. The method of manufacturing a semiconductor device according to claim 1, wherein
the semiconductor substrate is a Si substrate, and
the (c) comprises forming at least a part of the insulating film by nitriding the inner surface of the hole.

8. The method of manufacturing a semiconductor device according to claim 1, wherein
the (c) comprises forming a conductive barrier film as the barrier film, and
the (d) comprises forming the conductive metal by electroplating using the conductive barrier film as current passing member.

9. The method of manufacturing a semiconductor device according to claim 1, wherein
the (c) comprises, after forming the insulating film, forming a TaN film as the barrier film on the insulating film.

10. The method of manufacturing a semiconductor device according to claim 9, wherein
the (d) comprises forming Cu as the conductive metal on the TaN film by electroplating using the TaN film as a seed layer.

11. A semiconductor device comprising:
a semiconductor substrate formed with a circuit on a surface thereof;
a through electrode which is provided to pass through the semiconductor substrate and to partly protrude from a back surface of the semiconductor substrate; and
a SiCN film which is provided to cover the back surface.

12. The semiconductor device according to claim 11, wherein the SiCN film has a composition that makes warping of the semiconductor substrate substantially zero.

13. The semiconductor device according to claim 11, wherein the SiCN film has a composition in which 2 at % to 40 at % C is added to Si₃N₄.

14. The semiconductor device according to claim 11, wherein the through electrode is covered with a barrier film against a material of the electrode and the barrier film is covered with an insulating film provided in contact with the semiconductor substrate.

15. The semiconductor device according to claim 14, wherein
the semiconductor substrate is a Si substrate, and
the insulating film comprises a Si₃N₄ film.

16. The semiconductor device according to claim 14, wherein a material of the barrier film is TaN.

17. The semiconductor device according to claim 11, wherein a material of the through electrode is Cu.
